(19) United States
(12) Patent Application Publication
(10) Pub. No.: US 2012/0168220 A1
(43) Pub. Date: Jul. 5, 2012

(54) MULTI-LAYER PRINTED CIRCUIT BOARD AND METHOD OF MANUFACTURING THE SAME

(75) Inventors: Han Ul Lee, Seoul (KR); Byung Bae SEO, Chungcheongbuk-do (KR); Chang Sup RYU, Gyunggi-do (KR); Yong Sam LEE, Gyunggi-do (KR)

(73) Assignee: SAMSUNG ELECTRO-MECHANICS CO., LTD., Gyunggi-do (KR)

(21) Appl. No.: 13/281,264

(22) Filed: Oct. 25, 2011

(30) Foreign Application Priority Data
Dec. 30, 2010 (KR) 10-2010-0138883

(51) Int. Cl. H05K 1/11; H01K 3/10

(52) U.S. Cl. 174/264; 174/262; 29/852

(57) ABSTRACT

Disclosed herein are a multi-layer printed circuit board and a method of manufacturing the same. In the multi-layer printed circuit board and the method of manufacturing the same, circuit layers formed in a plurality of insulating layers are electrically interconnected through vias formed in a lump, thereby making it possible to secure bonding reliability of an interlayer circuit layer and more stably secure performance of the printed circuit board. In addition, since a stacked type via structure may be implemented by performing a via hole drilling process, a desmear process, and a copper plating process only one time after an insulating layer and an circuit layer are stacked, a manufacturing process, a manufacturing time, and manufacturing costs of the stacked type via structure may be reduced.

### CROSS REFERENCE TO RELATED APPLICATION

This application claims the benefit of Korean Patent Application No. 10-2010-0138883, filed on Dec. 30, 2010, entitled “Multi-layer Printed Circuit Board and Method of Manufacturing The Same”, which is hereby incorporated by reference in its entirety into this application.

### BACKGROUND OF THE INVENTION

1. Technical Field

The present invention relates to a multi-layer printed circuit board and a method of manufacturing the same.

2. Description of the Related Art

A multi-layer printed circuit board is manufactured by forming an inner circuit layer on a surface of a core substrate such as a copper clad layer (CCL), or the like using an additive method, a subtractive method, or the like, sequentially stacking an insulating layer and a metal layer, and forming an outer circuit layer using the same method as the formation method of the inner circuit layer. In this case, interlayer electrical connection in the printed circuit board is performed through a process of drilling a hole in the printed circuit board and chemically/electrically plating an inner portion of the hole. As a representative type of various types of holes used in the printed circuit board, there is a plated through hole (PTH) or a blind via hole (BVH). The plated through hole completely penetrates through the printed circuit board, is mainly used for interlayer connection of a double-sided printed circuit board or interlayer connection in a core layer of a multi-layer printed circuit board, and has a cylindrical shape having a predetermined-size cross section. The blind via hole has a structure in which one surface thereof is closed, and is mainly used for electrical connection between a base layer and a stacked layer of the multi-layer printed circuit board. The blind via hole is formed through laser drilling, and a cross section of the blind via hole has an inverse trapezoidal shape in which a hole size of a portion irradiated with a laser beam is larger than that of a bottom surface thereof. As a via formed in the printed circuit board using a build up method, there are a staggered type via structure, a stacked type via structure, and the like.

FIG. 1 is a cross-sectional view of a multi-layer printed circuit board having a staggered type via structure according to the prior art. As shown in FIG. 1, electrical connection between a plated through hole 1 and a blind via hole 2 according to the prior art has been implemented through a staggered type via structure. That is, an inner portion of the plated through hole 1 has not yet been filled with copper plating, and the blind via hole 2 has been formed, while being staggered with the plated through hole 1 due to limitation in matching force between the plated through hole 1 and the blind via hole 2 in performing laser drilling in order to form the blind via hole 2.

Meanwhile, as the printed circuit board having high density has been gradually manufactured, the development for the stacked type via structure in which the blind via hole 2 is formed directly on an upper portion of the plated through hole 1 has been continuously conducted. That is, the stacked type via structure has the plated through hole 1 and the blind via hole 2 formed in a straight line. A method of manufacturing the stacked type via structure will be described First, the plated through hole is drilled in a core layer by using a laser drill. In this case, the plated through hole may be drilled by a computerized numerical control drill using a drill bit. Then, an inner portion of the plated through hole is plated to form an inner circuit layer. In this case, since the plated through hole is conducted to the blind via hole in a straight line, the inner portion of the plated through hole is plated so that it is completely filled and a dimple (a small dent on a surface thereof) is not generated. Thereafter, an insulating layer such as a prepreg, or the like, and a metal layer such as a copper foil, or the like, is sequentially stacked on both surfaces of the core layer. Here, the metal layer is formed as an outer circuit layer through a tenting method in a process described below. Next, the blind via hole is drilled by using a laser drill to penetrate through the insulating layer and the metal layer. In this case, the blind via hole is arranged to be in line with the plated through hole. Then, an inner portion of the blind via hole is plated and the metal layer is selectively etched to form the outer circuit layer.

As such, the printed circuit board according to the prior art has used a method in which the plated through hole and the blind via hole are connected to each other to perform interlayer conduction, thereby contributing to slimness and lightness and performance improvement of electronic products.

However, since the plated through hole and the blind via hole are separately manufactured in the stacked type via structure according to the prior art, there was a limitation in the matching force between the plated through hole and the blind via hole and there was a difficulty in securing bonding reliability at a contact portion between the plated through hole and the blind via hole. That is, as the printed circuit board having high density has been gradually manufactured, the demand for reductions in a hole size as well as in a line width of a circuit and a size of a land has been increased, and in the case in which the printed circuit board is designed so that the plated through hole of the core layer has a small diameter, there was a difficulty in reducing positional deviation between the plated through hole and the blind via hole.

In addition, since connection between the plated through hole and the blind via hole may be opened due to an error in laser drilling, an error in desmear, an error in plating, or the like, during the drilling of the blind via hole, each process should be accurately managed and monitoring sufficient so that the via open is not generated has been required.

Further, a manufacture process for implementing the stacked type via structure has been complicated, such that manufacturing costs thereof are increased. That is, since the plated through hole of the core layer should have the blind via hole formed directly on the upper portion thereof, it should be necessarily formed through fill plating. In addition, when the fill plating may not be performed using a fill plating equipment and plating solution, the plated through hole should be plated and then filled. Meanwhile, in order to form the blind via hole in the insulating layer formed on both surfaces of the core layer having the plated through hole formed therein, each of a drilling process, a desmear process, and a copper plating process should be performed two times. In addition, when the number of layers is increased, more processes should be repeated.

### SUMMARY OF THE INVENTION

The present invention has been made in an effort to provide a multi-layer printed circuit board capable of securing reliability of interlayer bonding by drilling vias of the multi-layer printed circuit board in a lump using laser beam, and a method of manufacturing the same.

According to a first preferred embodiment of the present invention, there is provided a multi-layer printed circuit board including: a base substrate; a first insulating layer formed on one surface of the base substrate; a second insulating layer formed on the other surface of the base substrate; a first via hole extended to a center surface of the base substrate, while penetrating through the first insulating layer, and having a shape in which a diameter thereof is decreased from the first insulating layer toward the center surface of the base substrate; a first via formed by plating an inner wall of the first via hole; a second via hole extended to the center surface of the base substrate, while penetrating through the second insulating layer, to correspond to the first via hole, having a shape in which a diameter thereof is decreased from the second insulating layer toward the center surface of the base substrate, and being in contact with the first via hole at the center surface of the base substrate; and a second via formed by plating an inner wall of the second via hole.

The multi-layer printed circuit board may further include: a first inner circuit layer formed on one surface of the base substrate and electrically connected to the first via; a second inner circuit layer formed on the other surface of the base substrate and electrically connected to the second via; a first outer circuit layer formed on the first insulating layer and electrically connected to the first via; and a second outer circuit layer formed on the second insulating layer and electrically connected to the second via.

The multi-layer printed circuit board may further include: a first inner circuit layer formed on one surface of the base substrate and electrically connected to the first via; a first outer circuit layer formed on the first insulating layer and electrically connected to the first via; and a second outer circuit layer formed on the second insulating layer and electrically connected to the second via.

The multi-layer printed circuit board may further include: a first inner circuit layer formed on one surface of the base substrate and electrically connected to the first via; a second inner circuit layer formed on the other surface of the base substrate and electrically connected to the second via; and a first outer circuit layer formed on the first insulating layer and electrically connected to the first via.

The multi-layer printed circuit board may further include: a first inner circuit layer formed on one surface of the base substrate and electrically connected to the first via; and a second inner circuit layer formed on the other surface of the base substrate and electrically connected to the second via.

The multi-layer printed circuit board may further include: a first outer circuit layer formed on the first insulating layer and electrically connected to the first via; and a second outer circuit layer formed on the second insulating layer and electrically connected to the second via.

The multi-layer printed circuit board may further include: a first inner circuit layer formed on one surface of the base substrate and electrically connected to the first via; and a first outer circuit layer formed on the first insulating layer and electrically connected to the first via.

The first and second vias may be formed through fill plating.

The first and second vias may have a shape in which the center surface of the base substrate is closed by plating.

The first and second vias may have a shape in which the center surface of the base substrate is penetrated through.

According to a second preferred embodiment of the present invention, there is provided a method of manufacturing a multi-layer printed circuit board, including: (A) forming a first insulating layer on one surface of the base substrate and forming a second insulating layer on the other surface of the base substrate; (B) forming a first via hole extended to a center surface of the base substrate, while penetrating through the first insulating layer, and having a shape in which a diameter thereof is decreased from the first insulating layer toward the center surface of the base substrate; (C) forming a second via hole extended to the center surface of the base substrate, while penetrating through the second insulating layer, to correspond to the first via hole, and having a shape in which a diameter thereof is decreased from the second insulating layer toward the center surface of the base substrate; and (D) forming a first via by plating an inner wall of the first via hole and forming a second via by plating an inner wall of the second via hole.

Step (A) may further include: (A′) forming a first inner circuit layer between one surface of the base substrate and the first insulating layer and forming a second inner circuit layer between the other surface of the base substrate and the second insulating layer, and the method of manufacturing a multi-layer printed circuit board may further include, after step (A), forming a first outer circuit layer on the first insulating layer to be electrically connected to the first via and forming a second outer circuit layer on the second insulating layer to be electrically connected to the second via, the first inner circuit layer being electrically connected to the first via and the second inner circuit layer being electrically connected to the second via.

Step (A) may further include: (A′) forming a first inner circuit layer between one surface of the base substrate and the first insulating layer, and the method of manufacturing a multi-layer printed circuit board may further include, after step (A), forming a first outer circuit layer on the first insulating layer to be electrically connected to the first via and forming a second outer circuit layer on the second insulating layer to be electrically connected to the second via, the first inner circuit layer being electrically connected to the first via.

Step (A) may further include: (A′) forming a first inner circuit layer between one surface of the base substrate and the first insulating layer and forming a second inner circuit layer between the other surface of the base substrate and the second insulating layer, and the method of manufacturing a multi-layer printed circuit board may further include, after step (A), forming a first outer circuit layer on the first insulating layer to be electrically connected to the first via, the first inner circuit layer being electrically connected to the first via and the second inner circuit layer being electrically connected to the second via.

Step (A) may further include: (A′) forming a first inner circuit layer between one surface of the base substrate and the first insulating layer and forming a second inner circuit layer between the other surface of the base substrate and the second insulating layer, the first inner circuit layer being electrically connected to the first via and the second inner circuit circuit layer being electrically connected to the second via.

The method of manufacturing a multi-layer printed circuit board may further include, after step (A), forming a first outer circuit layer on the first insulating layer to be electrically connected to the first via and forming a second outer circuit layer on the second insulating layer to be electrically connected to the second via.

Step (A) may further include: (A′) forming a first inner circuit layer between one surface of the base substrate and the first insulating layer, and, the method of manufacturing a multi-layer printed circuit board may further include, after step (A), forming a first outer circuit layer on the first insulating layer to be electrically connected to the first via, the first inner circuit layer being electrically connected to the first via.

The first and second vias may be formed through fill plating.

The first and second vias may have a shape in which the center surface of the base substrate is closed by plating.

The first and second vias may have a shape in which the center surface of the base substrate is penetrated through.

### BRIEF DESCRIPTION OF THE DRAWINGS

FIG. 1 is a cross-sectional view of a multi-layer printed circuit board according to the prior art;

FIGS. 2 to 10 are cross-sectional views of a multi-layer printed circuit board according to a preferred embodiment of the present invention; and

FIGS. 11 to 20 are cross-sectional views showing a method of manufacturing a multi-layer printed circuit board according to a preferred embodiment of the present invention in process sequence.

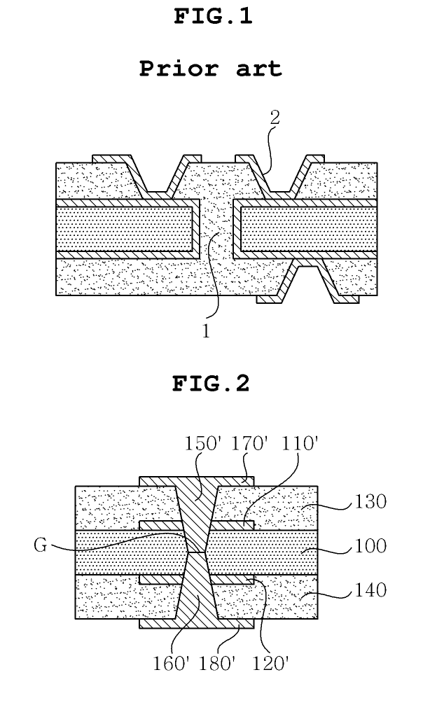

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Various objects, advantages and features of the invention will become apparent from the following description of embodiments with reference to the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Structure of Multi-Layer Printed Circuit Board

FIGS. 2 to 4 are cross-sectional views of a multi-layer printed circuit board according to a preferred embodiment of the present invention.

As shown in FIG. 2, a multi-layer printed circuit board according to a preferred embodiment of the present invention is configured to include a base substrate 100, a first inner circuit layer 110′ and a first insulating layer 130 which are formed on one surface of the base substrate 100, a second inner circuit layer 120′ and a second insulating layer 140 which are formed on the other surface of the base substrate 100, a first via 150′ extended to a center surface G of the base substrate, while penetrating through the first insulating layer 130, and having a shape in which a diameter thereof is decreased from the first insulating layer 130 toward the center surface G of the base substrate, a second via 160′ extended to the center surface G of the base substrate, while penetrating through the second insulating layer 140, to correspond to the first via 150′ and having a shape in which a diameter thereof is decreased from the second insulating layer 140 toward the center surface G of the base substrate, a first outer circuit layer 170′ formed on the first insulating layer 130, and a second outer circuit layer 180′ formed on the second insulating layer 140.

The base substrate 100 may be made of an insulating material generally used for a printed circuit board. As the insulating material, for example, a polymer resin such as prepreg (PPG), an epoxy based resin such as FR-4, BT, etc, an Ajinomoto build-up film (ABF), or the like, may be used. In addition, the insulating layers (the first insulating layer 130 and the second insulating layer 140) made of the same material as the material used for the base substrate 100 may be stacked on the base substrate 100. Although the accompanying drawings of the present invention has shown a three-layer structure in which the insulating layers are stacked on both surfaces of the base substrate 100, the present invention may use a base substrate 100 formed of a multi-layer such as three or more layers according to use purpose.

The inner circuit layers 110′ and 120′ are formed on one surface and the other surface of the base substrate 100. The first inner circuit layer 110′ formed on one surface of the base substrate 100 is conducted to the first via 150′ and the second inner circuit layer 120′ formed on the other surface of the base substrate 100 is conducted to the second via 160′. The inner circuit layers 110′ and 120′ are generally preferably made of copper; however, a material of the inner circuit layers 110′ and 120′ is not limited thereto.

Each of the outer circuit layers 170′ and 180′ is formed on each of the insulating layers 130 and 140, and is conducted to each of the inner circuit layers 110′ and 120′ through each of the vias 150′ and 160′. The first outer circuit layer 170′ formed on the first insulating layer 130 is electrically connected to the first inner circuit layer 110′ through the first via 150′, and the second outer circuit layer 180′ formed on the second insulating layer 140 is electrically connected to the second inner circuit layer 120 through the second via 160′. In addition, since the first via 150′ and the second via 160′ are in contact with each other at the center surface G of the base substrate, the first outer circuit layer 170′, the first inner circuit layer 110′, the second inner circuit layer 120′, and the second outer circuit layer 180′ are conducted. Similar to the inner circuit layers 110′ and 120′, the outer circuit layers 170′ and 180′ are generally preferably made of copper; however, a material of the outer circuit layers 170′ and 180′ is not limited thereto.

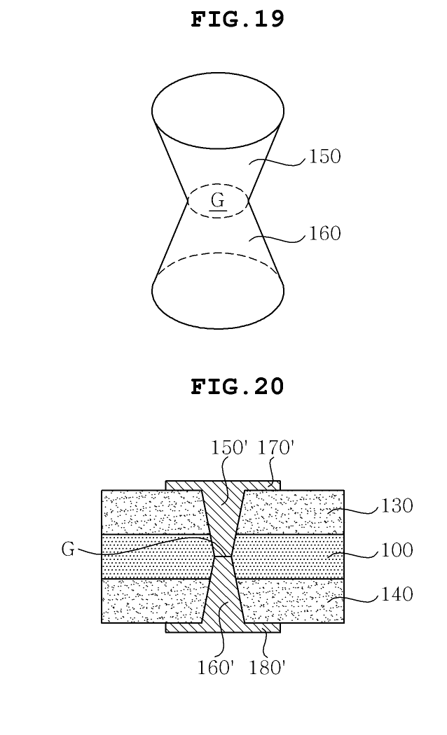

The vias 150′ and 160′ include the first via 150′ extended to the center surface G of the base substrate, while penetrating through the first outer circuit layer 170′, the first insulating layer 130, and the first inner circuit layer 110′, and the second via 160′ extended to the center surface G of the base substrate, while penetrating through the second outer circuit layer 180′, the second insulating layer 140, and the second inner circuit layer 120′. Here, the center surface (G; See FIG. 19) of the base substrate indicates a cross section formed when a center of a sandglass shaped structure formed by contacting the first via 150′ to the second via 160′ is cut. The first via 150′ has a structure in which a diameter thereof is decreased toward the center surface G of the base substrate, and the second via 160′ has a structure in which a diameter thereof is decreased toward the center surface G of the base substrate. When a hole is drilled using laser beam 400 (See FIG. 16), the laser beam 400 has higher energy toward a center thereof, such that an inner wall of the hole has a tapered shape (a shape in which both surfaces opposite to each other are symmetrically inclined). Generally, the first via 150′ and the second via 160′ have a sandglass shape in which a diameter thereof is minimal at the center surface G of the base substrate.

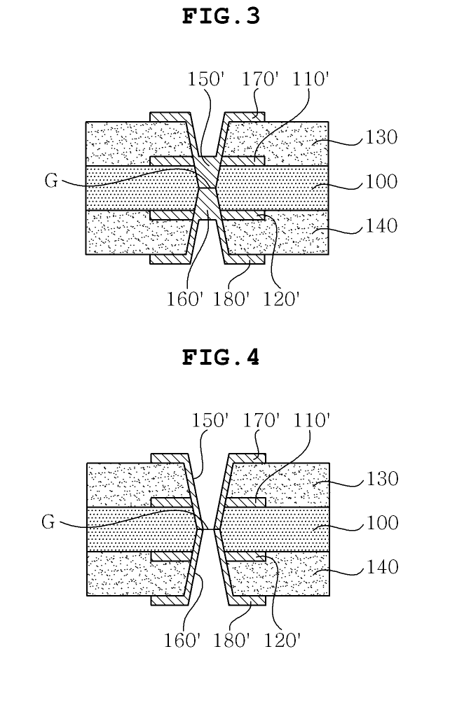

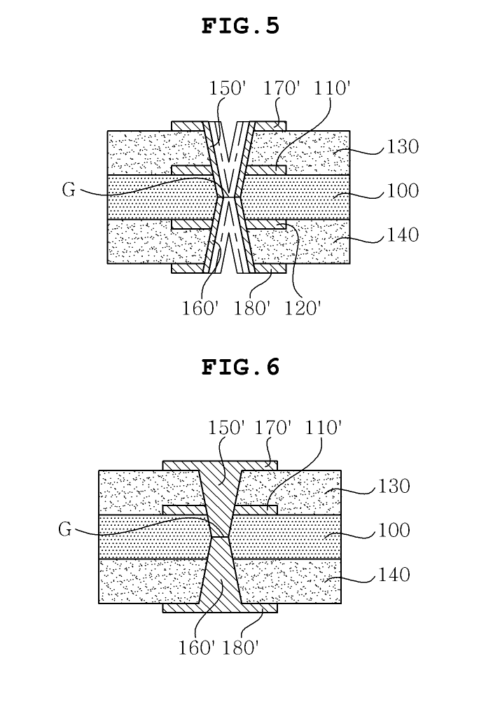

Meanwhile, the present invention may implement the multi-layer printed circuit board including the vias 150′ and 160 having various inner shapes. A preferred embodiment thereof is as shown in FIGS. 3 and 4. A process for forming vias will be described in detail with reference to FIG. 5.

First, as shown in FIG. 3, the first via 150′ and the second via 160′ may be formed through half-fill plating. The first via 150′ is formed by plating an inner wall of a first via hole 150 (See FIG. 18), and the second via 160′ is formed by plating an inner wall of a second via hole 160 (See FIG. 18). As plating layers formed during a plating process become gradually thicker from the inner walls of both via holes 150 and 160, the plating layer of the first via hole 150 and the plating layer of the second via hole 160 are in contact with each other at the center surface G of the base substrate and are grown to have a predetermined thickness (See FIG. 5). When the first via hole 150 and the second via hole 160 are drilled to be in contact with each other at the center surface G of the base substrate, the entire shape of the first via hole 150 and the second via hole 160 is similar to the sandglass shape. In this case, as the plating layers are grown along a tapered shape of the inner walls of the via holes 150 and 160, the plating layers are in contact with each other at a portion at which a diameter of the sandglass shape becomes minimal (that is, the center surface G of the base substrate) and are grown to have a predetermined thickness.

In addition, as shown in FIG. 4, the first via 150′ and the second via 160′ may be formed through none-fill plating. That is, the first via 150′ is formed by plating the inner wall of the first via hole 150, and the second via 160′ is formed by plating the inner wall of the second via hole 160, wherein the plating layers formed during the plating process become gradually thicker from the inner walls of both via holes 150 and 160 (See FIG. 5). In this case, the via according to the present embodiment, which is manufactured by forming the plating layers only before the first via 150′ is in contact with the second via 160′ at the center surface G of the base substrate, has a shape in which it penetrate through the center surface G of the base substrate.

FIGS. 6 to 10 show a structure of a multi-layer printed circuit board capable of being variously modified according to a preferred embodiment of the present invention. Since components in FIGS. 6 to 10 are the same as the above-mentioned components, a detailed description thereof will be omitted. A multi-layer printed circuit board described below includes the base substrate 100 of claim 1, the first insulating layer 130 formed on one surface of the base substrate 100, the second insulating layer 140 of the other surface of the base substrate 100, the first via 150′ and the second via 160′, as a basic structure.

First, a multi-layer printed circuit board show in FIG. 6 further includes the first inner circuit layer 110′ formed on one surface of the base substrate 100, the first outer circuit layer 170′ formed on the first insulating layer 130, and the second outer circuit layer 180′ formed on the second insulating layer 140, in addition to the basic structure.

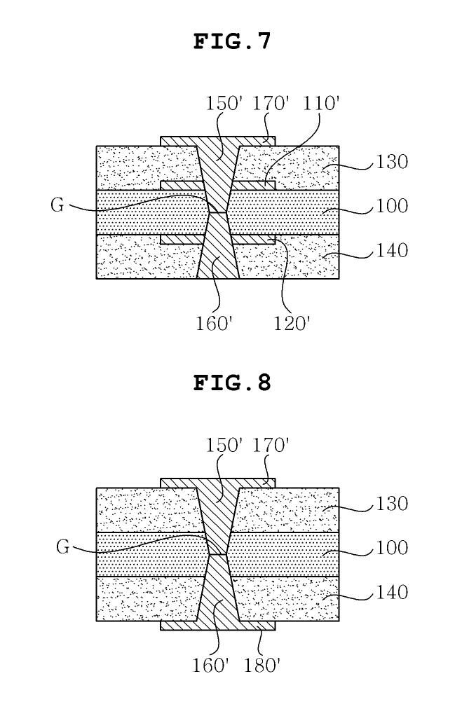

Next, a multi-layer printed circuit board show in FIG. 7 further includes the first inner circuit layer 110′ formed on one surface of the base substrate 100, the second inner circuit layer 120′ formed on the other surface of the base substrate 100, and the first outer circuit layer 170′ formed on the first insulating layer 130, in addition to the basic structure.

Next, a multi-layer printed circuit board show in FIG. 8 further includes the first outer circuit layer 170′ formed on the first insulating layer 130 and the second outer circuit layer 180′ formed on the second insulating layer 140, in addition to the basic structure.

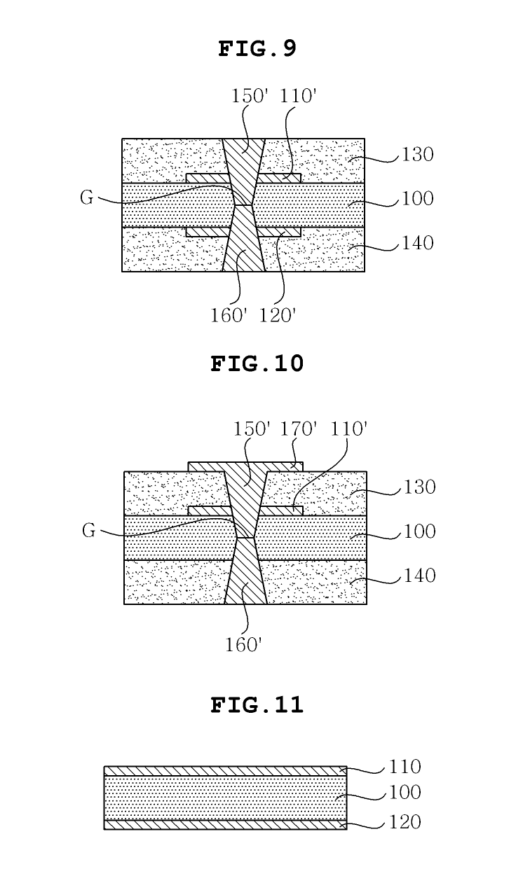

Next, a multi-layer printed circuit board show in FIG. 9 further includes the first inner circuit layer 110′ formed on one surface of the base substrate 100 and the second inner circuit layer 120′ formed on the other surface of the base substrate 100, in addition to the basic structure.

Next, a multi-layer printed circuit board show in FIG. 10 further includes the first inner circuit layer 110′ formed on one surface of the base substrate 100 and the first outer circuit layer 170′ formed on the first insulating layer 130, in addition to the basic structure.

Method of Manufacturing Multi-Layer Printed Circuit Board

FIGS. 11 to 20 are cross-sectional views showing a method of manufacturing a multi-layer printed circuit board according to a preferred embodiment of the present invention in processing sequence. Hereinafter, a method of manufacturing a multi-layer printed circuit board will be described based on the structure of the multi-layer printed circuit board shown in FIG. 2.

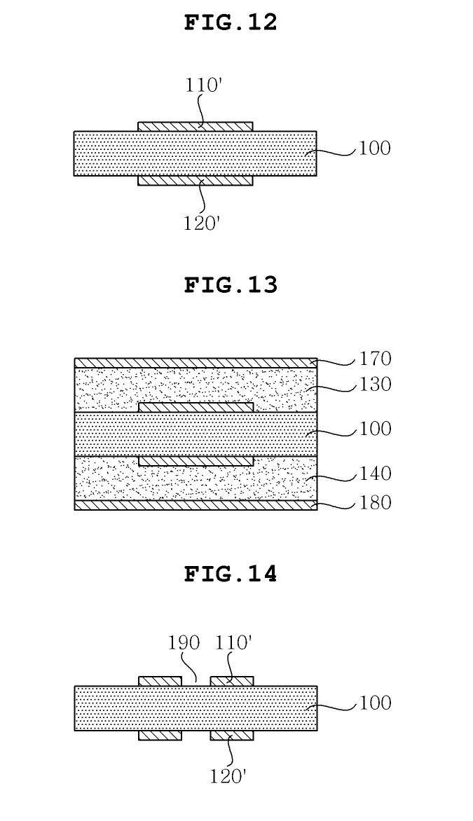

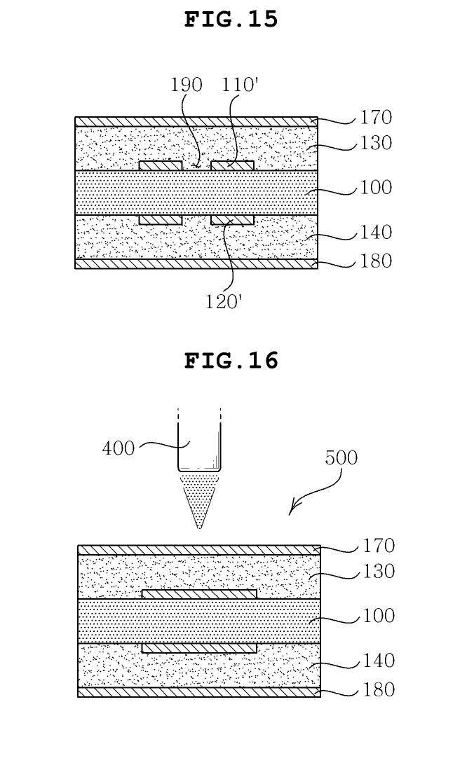

First, as shown in FIGS. 11 and 12, a member having the metal layers 110 and 120 formed on both surfaces of the base substrate 100 is prepared (FIG. 11), and the inner circuit layers 110′ and 120′ is formed by processing the metal layers 110 and 120 (FIG. 12). Describing in detail, dry films are applied to the metal layers 110 and 120 formed on one surface and the other surface of the base substrate 100, and ultraviolet rays are irradiated thereto in a state in which the metal layers 110 and 120 are blocked by a mask. Then, when developer is applied to the dry films, a portion that is cured by irradiation of the ultraviolet ray remains as it is; however, a portion that is not cured is removed, such that an etching resist pattern is formed. Next, the metal layers 110 and 120 in a portion exposed from the etching resist pattern are removed through etching, and the etching resist pattern is peeled off, such that the inner circuit layers 110′ and 120′ are formed. A subtractive method described in the present embodiment is only an example. As a general method of forming a circuit pattern on an insulating layer, there are an additive method, a semi-additive method, a modified semi-additive method, and the like, in addition to the subtractive method. However, in a process described below, since the via holes 150 and 160 penetrate through the inner circuit layers 110′ and 120′, thicknesses of the inner circuit layers 110′ and 120′ are preferably maintained to be 8 μm or less so that the laser beam 400 more easily penetrates through the inner circuit layers 110′ and 120′. Meanwhile, as shown in FIGS. 14 and 15, a method in which an opening 190 is first formed in the inner circuit layers 110′ and 120 and the via holes 150 and 160 are formed to penetrate through the opening 190 may be used in the method of manufacturing a multi-layer printed circuit board according to a preferred exemplary embodiment of the present invention. In this case, in order to previously prevent the inner circuit layers 110′ and 120′ from being damaged due to irradiation of the laser beam 400, the inner circuit layers 110′ and 120′ are preferably formed to have a thickness of 10 μm or more.

Then, as shown in FIG. 13, the first insulating layer 130 is formed on one surface of the base substrate 100, and the second insulating layer 140 is formed on the other surface of the base substrate 100. Thereafter, the first metal layer 170 is formed on the first insulating layer 130, and the second metal layer 180 is formed on the second insulating layer 140. A method of stacking resin clad coppers (RCC; a material having the insulating layer coated on a copper foil) on both surfaces of the base substrate 100 may be used. Here, the first metal layer 170 and the second metal layer 180 will become the outer circuit layers 170′ and 180′ through a process described below. However, the outer circuit layers 170′ and 180′ may be not only previously formed before the vias 150′ and 160′ are formed, but may also be formed to be conducted to the vias 150′ and 160′ after the vias 150′ and 160′ are formed. Similar to the inner circuit layers 110′ and 120′, the outer circuit layers 170′ and 180′ may also be formed by using a general method of forming the circuit pattern on the insulating layers (the first insulating layer 130 and the second insulating layer 140), that is, the subtractive method, the additive method, the semi-additive method, the modified semi-additive method (MSAP), and the like.

Meanwhile, as shown in FIGS. 14 and 15, a method of forming the opening 190 corresponding to a portion at which the via holes 150 and 160 are drilled in the inner circuit layers 110′ and 120′ and then, drilling the via holes 150 and 160 to penetrate through the metal layers 170 and 180, and the insulating layers 130 and 140, and the base substrate 100 may also be used. While an operation of forming the opening 190 may be selectively omitted in the case in which the via holes 150 and 160 are drilled using an yttrium aluminum garnet (YAG) laser beam, the opening 190 should be necessarily formed in the case in which the via holes 150 and 160 are drilled using a CO₂ laser beam. In this case, a defect such as deformation or change of the inner circuit layers 110′ and 120′ due to the laser beam 400 penetrated therethrough may be previously prevented, and only the insulating layers 130 and 140 are drilled rather than the metal layers such as the inner circuit layers 110′ and 120′, such the drilling of the via holes 150 and 160 becomes easier. The via holes 150 and 160 may be drilled using any one of a conformal laser drilling method, a copper direct drilling method, and a YAG laser drilling method, such that a drilling equipment is not limited.

Then, as shown in FIGS. 16 to 18, the via holes 150 and 160 penetrating through the entirety of a multi-layer member 500 are drilled using a laser 400 drill. The laser 400 drill may drill only one surface of the multi-layer member 500 or may sequentially drill both surfaces of the multi-layer member 500; however, the both surfaces of the multi-layer member 500 are preferably drilled in order to facilitate the plating of the via holes 150 and 160.

As a method of forming the via holes 150 and 160, a conformal laser drilling method or a copper direct drilling method may be used. In addition, the via holes 150 and 160 may be formed using the YAG laser beam 400. That is, the metal layers (the first metal layer 170 and the second metal layer 180) formed on the both surfaces of the multi-layer member 500 are exposed and etched to form an opening (not shown) at the portion at which the via holes 150 and 160 are drilled and the via holes 150 and 160 are then formed in the insulating layers using the CO₂ laser beam 400 (the conformal laser drilling method), or half etching processing is performed on the metal layers 170 and 180 formed on the multi-layer member 500 to make a thickness of the metal layers 170 and 180 thin, black oxide processing is performed on the multi-layer member 500, and the via holes 150 and 160 are then formed in the insulating layers using the CO₂ laser beam 400 (the copper direct drilling method) In the copper direct drilling method, the half etching processing may be omitted according to a thickness condition of the metal layers 170 and 180. Meanwhile, when the via holes 150 and 160 are drilled by the YAG laser beam 400, the metal layers (for example, a copper foil layer) may also be drilled, such that there is no need to form a separate opening.

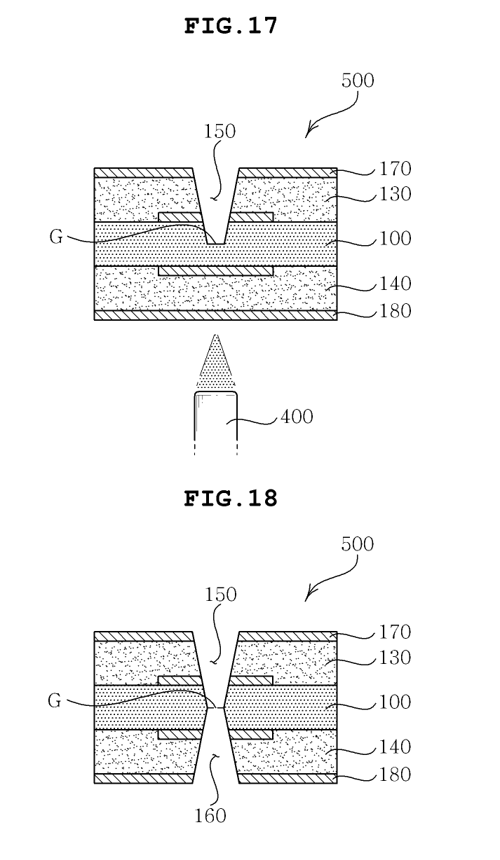

The first via hole 150 is formed to be extended to the center surface G of the base substrate, while penetrating through the first metal layer 170, the first insulating layer 130, and the first inner circuit layer 110′ (in the case in which a portion of the first metal layer 170 is removed using the conformal laser drilling method, the first insulating layer 130 and the first inner circuit layer 110′), in one surface (the surface on which the first metal layer 170 is formed) of the multi-layer member 500 (See FIGS. 16 and 17). Since the laser beam 400 has higher energy toward a center thereof, the first via hole 150 has a shape in which a diameter thereof is decreased toward the center surface G of the base substrate, that is, the tapered shape. In this case, the first via hole 150 may be drilled to be somewhat deeper than the center surface G of the base substrate so that it is in contact with the second via hole 160 formed in a process described below at the center surface G (meaning a virtual surface on which the first via 150′ and the second via 160′ are in contact with each other; See FIG. 19) of the base substrate. Then, the second via hole 160 is formed to be extended to the center surface G of the base substrate, while penetrating through the second metal layer 180, the second insulating layer 140, and the second inner circuit layer 120′ (in the case in which a portion of the second metal layer 180 is removed using the conformal laser drilling method, the second insulating layer 140 and the second outer circuit layer 180′), in the other surface (the surface on which the first second layer 180 is formed) of the multi-layer member 500 (See FIG. 18) Similar to the first via hole 150, the second via hole 160 has a shape in which a diameter thereof is decreased toward the center surface G of the base substrate, that is, the tapered shape. When the via holes 150 and 160 are formed by a mechanical drilling method, the via holes 150 and 160 are implemented to have a cylindrical shape. However, when the via holes 150 and 160 are formed in both surfaces of the multi-layer member 500 by the laser (400) drilling method according to a preferred embodiment of the present invention, the via hole penetrates through the entirety of the multi-layer member 500, while having the entire shape similar to that of the sandglass. The sandglass shaped via hole has a decreased diameter at the center surface thereof, thereby making it possible to further increase plating capability within the through hole.

Next, as shown in FIG. 20, the plating layers are formed in the inner walls of the first via hole 150 and the second via hole 160 to form the first via 150′ and the second via 160′. In this case, the vias 150′ and 160′ may be formed by using a general process. More specifically, a seed layer is formed to have a minimal thickness by using electroless plating and the vias 150′ and 160′ are then formed by using electroplating. Next, the first metal layer 170 is selectively etched to form the first outer circuit layer 170′, and the second metal layer 180 is selectively etched to form the second outer circuit layer 180′.

With the multi-layer printed circuit board and the method of manufacturing the same according to the preferred embodiment of the present invention, the circuit layers formed in a plurality of insulating layers are electrically interconnected through the vias formed in a lump, thereby making it possible to secure bonding reliability of the interlayer circuit layer and more stably ensure performance of the printed circuit board.

In addition, since the stacked type via structure may be implemented by performing a via hole drilling process, a desmear process, and a copper plating process only one time after the insulating layer and the circuit layer are stacked, the manufacturing process, the manufacturing time, and the manufacturing costs of the stacked type via structure may be reduced.

Further, the via hole is drilled using the laser beam, such that an inner wall of the via hole has a tapered shape, thereby making it possible to facilitate the fill plating of the inner portion of the via hole and prevent defect such as void generated in the inner portion of the via hole.

Although the preferred embodiments of the present invention have been disclosed for illustrative purposes, they are for specifically explaining the present invention and thus the multi-layer printed circuit board and the method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A multi-layer printed circuit board comprising:
a base substrate;
a first insulating layer formed on one surface of the base substrate;
a second insulating layer formed on the other surface of the base substrate;
a first via hole extended to a center surface of the base substrate, while penetrating through the first insulating layer, and having a shape in which a diameter thereof is decreased from the first insulating layer toward the center surface of the base substrate;
a first via formed by plating an inner wall of the first via hole;
a second via hole extended to the center surface of the base substrate, while penetrating through the second insulating layer, to correspond to the first via hole, having a shape in which a diameter thereof is decreased from the second insulating layer toward the center surface of the base substrate, and being in contact with the first via hole at the center surface of the base substrate; and
a second via formed by plating an inner wall of the second via hole.

2. The multi-layer printed circuit board as set forth in claim 1, further comprising:
a first inner circuit layer formed on one surface of the base substrate and electrically connected to the first via;
a second inner circuit layer formed on the other surface of the base substrate and electrically connected to the second via;
a first outer circuit layer formed on the first insulating layer and electrically connected to the first via; and
a second outer circuit layer formed on the second insulating layer and electrically connected to the second via.

3. The multi-layer printed circuit board as set forth in claim 1, further comprising:
a first inner circuit layer formed on one surface of the base substrate and electrically connected to the first via;
a first outer circuit layer formed on the first insulating layer and electrically connected to the first via; and
a second outer circuit layer formed on the second insulating layer and electrically connected to the second via.

4. The multi-layer printed circuit board as set forth in claim 1, further comprising:
a first inner circuit layer formed on one surface of the base substrate and electrically connected to the first via;
a second inner circuit layer formed on the other surface of the base substrate and electrically connected to the second via; and
a first outer circuit layer formed on the first insulating layer and electrically connected to the first via.

5. The multi-layer printed circuit board as set forth in claim 1, further comprising:
a first inner circuit layer formed on one surface of the base substrate and electrically connected to the first via; and
a second inner circuit layer formed on the other surface of the base substrate and electrically connected to the second via.

6. The multi-layer printed circuit board as set forth in claim 1, further comprising:
a first outer circuit layer formed on the first insulating layer and electrically connected to the first via; and
a second outer circuit layer formed on the second insulating layer and electrically connected to the second via.

7. The multi-layer printed circuit board as set forth in claim 1, further comprising:
a first inner circuit layer formed on one surface of the base substrate and electrically connected to the first via; and
a first outer circuit layer formed on the first insulating layer and electrically connected to the first via.

8. The multi-layer printed circuit board as set forth in claim 1, wherein the first and second vias are formed through fill plating.

9. The multi-layer printed circuit board as set forth in claim 1, wherein the first and second vias have a shape in which the center surface of the base substrate is closed by plating.

10. The multi-layer printed circuit board as set forth in claim 1, wherein the first and second vias have a shape in which the center surface of the base substrate is penetrated through.

11. A method of manufacturing a multi-layer printed circuit board, comprising:
(A) forming a first insulating layer on one surface of the base substrate and forming a second insulating layer on the other surface of the base substrate;
(B) forming a first via hole extended to a center surface of the base substrate, while penetrating through the first insulating layer, and having a shape in which a diameter thereof is decreased from the first insulating layer toward the center surface of the base substrate;
(C) forming a second via hole extended to the center surface of the base substrate, while penetrating through the second insulating layer, to correspond to the first via hole, and having a shape in which a diameter thereof is decreased from the second insulating layer toward the center surface of the base substrate; and
(D) forming a first via by plating an inner wall of the first via hole and forming a second via by plating an inner wall of the second via hole.

12. The method of manufacturing a multi-layer printed circuit board as set forth in claim 11, wherein step (A) further includes:
(A′) forming a first inner circuit layer between one surface of the base substrate and the first insulating layer and forming a second inner circuit layer between the other surface of the base substrate and the second insulating layer, and
the method of manufacturing a multi-layer printed circuit board further includes, after step (A), forming a first outer circuit layer on the first insulating layer to be electrically connected to the first via and forming a second outer circuit layer on the second insulating layer to be electrically connected to the second via,
the first inner circuit layer being electrically connected to the first via and the second inner circuit layer being electrically connected to the second via.

13. The method of manufacturing a multi-layer printed circuit board as set forth in claim 11, wherein step (A) further includes:
(A′) forming a first inner circuit layer between one surface of the base substrate and the first insulating layer, and,
the method of manufacturing a multi-layer printed circuit board further includes, after step (A), forming a first outer circuit layer on the first insulating layer to be electrically connected to the first via and forming a second outer circuit layer on the second insulating layer to be electrically connected to the second via,
the first inner circuit layer being electrically connected to the first via.

14. The method of manufacturing a multi-layer printed circuit board as set forth in claim 11, wherein step (A) further includes:
(A′) forming a first inner circuit layer between one surface of the base substrate and the first insulating layer and forming a second inner circuit layer between the other surface of the base substrate and the second insulating layer, and,
the method of manufacturing a multi-layer printed circuit board further includes, after step (A), forming a first outer circuit layer on the first insulating layer to be electrically connected to the first via,
the first inner circuit layer being electrically connected to the first via and the second inner circuit layer being electrically connected to the second via.

15. The method of manufacturing a multi-layer printed circuit board as set forth in claim 11, wherein step (A) further includes:
(A′) forming a first inner circuit layer between one surface of the base substrate and the first insulating layer and forming a second inner circuit layer between the other surface of the base substrate and the second insulating layer, and,
the first inner circuit layer being electrically connected to the first via and the second inner circuit circuit layer being electrically connected to the second via.

16. The method of manufacturing a multi-layer printed circuit board as set forth in claim 11, further comprising, after step (A), forming a first outer circuit layer on the first insulating layer to be electrically connected to the first via and forming a second outer circuit layer on the second insulating layer to be electrically connected to the second via.

17. The method of manufacturing a multi-layer printed circuit board as set forth in claim 11, wherein step (A) further includes:
(A′) forming a first inner circuit layer between one surface of the base substrate and the first insulating layer, and,
the method of manufacturing a multi-layer printed circuit board further includes, after step (A), forming a first outer circuit layer on the first insulating layer to be electrically connected to the first via,
the first inner circuit layer being electrically connected to the first via.

18. The method of manufacturing a multi-layer printed circuit board as set forth in claim 11, wherein the first and second vias are formed through fill plating.

19. The method of manufacturing a multi-layer printed circuit board as set forth in claim 11, wherein the first and second vias have a shape in which the center surface of the base substrate is closed by plating.

20. The method of manufacturing a multi-layer printed circuit board as set forth in claim 11, wherein the first and second vias have a shape in which the center surface of the base substrate is penetrated through.
